(19) United States
(12) Patent Application Publication
(10) Pub. No.: US 2021/0273279 A1
(43) Pub. Date: Sep. 2, 2021

(54) Module for a Motor Vehicle

(71) Applicant: Bayerische Motoren Werke Aktiengesellschaft, Muenchen (DE)

(72) Inventors: Simon HETTENKOFER, Muenchen (DE); Sebastian KLOSS, Muenchen (DE); Alexander ROTHMAYER, Bad Endorf (DE); Anis SELLAOUTI, Muenchen (DE); Philippe STAUDINGER, Muenchen (DE); Guenther TUSCHL, Kolbermoor (DE); Roland Constantin VALLERY, Wien (AT); Aleksandar VRHOVAC, Muenchen (DE)

(21) Appl. No.: 17/258,200

(22) PCT Filed: Jul. 1, 2019
(86) PCT No.: PCT/EP2019/067562

§ 371 Date: Jan. 6, 2021

(30) Foreign Application Priority Data
Jul. 6, 2018 (DE) 10 2018 211 220.7
Jul. 6, 2018 (DE) 10 2018 211 221.5
Jul. 6, 2018 (DE) 10 2018 211 222.3
Jul. 6, 2018 (DE) 10 2018 211 223.1
Jul. 6, 2018 (DE) 10 2018 211 225.8

(51) Int. Cl. H01M 10/6556; H01M 10/613; H01M 10/625; H01M 10/6551; H05K 7/20

(52) U.S. Cl. CPC H01M 10/6556; H01M 10/613; B60K 2001/0438; H01M 10/6551; H05K 7/20272; H01M 10/625

(57) ABSTRACT

A module for a motor vehicle includes at least one operating fluid container, at least one energy storage device, and a cooling device. The at least one operating fluid container is configured to store an operating fluid which is liquid under ambient conditions. The at least one energy storage device is configured to store electrical energy. The cooling device with at least one cooling element is configured to commonly cool the operating medium container and the energy storage device.

### BACKGROUND AND SUMMARY OF THE INVENTION

The technology disclosed here relates to a motor vehicle having an operating fluid container and a high-voltage accumulator. Motor vehicles may include an operating fluid container and a high-voltage accumulator.

High-voltage accumulator systems and fuel supply systems are used, for example, in electrified and hybridized motor vehicles (e.g. mild hybrid, plug-in hybrid (PHEV), hybrid, BEV with REX, FCEV, etc.). A high-voltage accumulator system and a fuel supply system have not only the storage cells and the operating fluid container but also numerous further components. Positioning all the components of the high-voltage accumulator system and of the fuel supply system in an installation space which is inter alia relevant for customer use (e.g. passenger compartment, trunk) causes this space to be severely reduced. All these components have their own housing and are mounted separately on the motor vehicle. The need to be able to mount the components, which has to be ensured, can result in non-optimum component shapes. The connection of the individual components can have adverse effects on the line lengths and on the expenditure on cabling, in particular in the case of components which are difficult to access. Unprotected lines along the underbody could be damaged on poor quality underlying surfaces.

Under certain circumstances multiple mounting aids may be necessary in the mounting process. The mounting work in these installation spaces is generally carried out in a clocked fashion following a complex mounting sequence. If a plurality of mounting steps have to be carried out in succession in installation spaces which are difficult to access, this can give rise to increased expenditure of time, in particular if components and subcomponents have to be mounted both in the underfloor, in the wheel housings and in other installation spaces of the motor vehicle.

At present, a fluid cooling system, connected to a conventional cooling circuit, is generally used to cool high-voltage accumulator systems. Operating fluid containers are not cooled. Increased and/or nonhomogeneous temperatures can bring about an increased instance of gas and therefore a rise in pressure in the fuel container and/or a greater requirement for scavenging air for scavenging the activated carbon filter.

Separate components can therefore entail disadvantages in respect of weight, installation space requirement, rigidity of the vehicle bodywork, mounting and component costs and/or ease of maintenance. The arrangement of the high-voltage accumulator in the trunk also brings about a raised overall center of gravity of the vehicle, which can result in disadvantages in terms of vehicle movement dynamics.

A preferred object of the technology disclosed here is at least to reduce a disadvantage of a previous solution, or to eliminate said disadvantage or to propose an alternative solution. In particular, a preferred object of the technology disclosed here is to improve the integration of an operating fluid container and an energy store, in particular in respect of utilization of installation space, weight, manufacturing costs, mounting, rigidity of the bodywork, robustness, safety and/or gas emissions. Further preferred objects can result from the advantageous effects of the technology disclosed here. The object/objects is/are achieved by means of the subject matter of patent claim 1 and the further claims. The dependent claims present preferred refinements.

The technology disclosed here relates to a module for a motor vehicle. The module comprises at least one operating fluid container for storing operating fluid which is liquid under ambient conditions, in particular in a storage volume S. The module further comprises at least one energy storage device for storing electrical energy.

A module is a group of components which fulfill a common purpose through their interaction. The module preferably fulfills the purpose that the components of the module are pre-assembled before being mounted on the bodywork of the motor vehicle, and are subsequently mounted onto the bodywork in a mounting step.

The technology disclosed here also comprises a motor vehicle with the module disclosed here. It is to be noted that the technology disclosed here can be used with any type of vehicle which has an energy storage device and an operating fluid container. The technology is preferably used in the following vehicle types: hybrid electric vehicles (HEVs), plug-in hybrid electric vehicles (PHEVs), battery electric vehicles (BEVs) and fuel cell vehicles (FCEVs).

A preferred operating fluid is fuel. It is equally conceivable that the technology disclosed here is used to store other fluids (e.g. water or an aqueous solution) in a motor vehicle. Even if an operating fluid container, operating fluid pump and the like are referred to here, the terms fuel container or fuel pump are equally also intended to be disclosed.

The technology disclosed here relates to an operating fluid container which forms the storage volume for storing the operating fluid. The operating fluid container therefore forms essentially the fluidtight outer shell of the storage volume and bounds the storage volume with respect to the installation space. In the case of plastic containers, the term bubble is used, for example.

The operating fluid container can be manufactured at least partially from a metal, in particular from aluminum, an aluminum alloy, steel or a steel alloy. The metal can be expediently coated, for example with a plastic layer which is impermeable to operating fluid. Alternatively or additionally, the metal can be anodized. Alternatively, the operating fluid container can be formed from a plastic, in particular with a multi-layer design with a layer which is impermeable to the operating fluid, such as a layer made of ethylene-vinyl alcohol copolymer (EVOH). The operating fluid container is expediently embodied in such a way that the operating fluid container is permeation-tight with respect to hydrocarbon emissions and/or resistant to contact with operating fluid.

The operating fluid container can have any suitable shape. In one refinement, the operating fluid container is embodied as a saddle container. A saddle container generally has two container chambers and a connecting region. The connecting region connects the two container chambers of the saddle container. In another refinement, the operating fluid container comprises a fluid chamber and a connecting region which projects beyond a central tunnel and is connected to the storage housing disclosed here. In a further refinement, the operating fluid container can have a single container chamber which widens toward the vehicle floor in the longitudinal direction of the vehicle (“a shoe shape”). Such a container chamber can extend essentially over the entire width of the rear seats.

The operating fluid container can expediently be embodied in multiple parts. For example, a lower shell and an upper shell can form the operating fluid container. In the three-part configuration, the lower shell, a central part and a cover can form the operating fluid container. The parts of the operating fluid container could equally also be combined in a different way. The operating fluid container or the storage housing can be manufactured, for example, by welding, pressure casting, blow molding, injection molding etc. At least part of the operating fluid container is advantageously manufactured together with the storage housing. The operating fluid container can have an opening for service work or mounting work.

The electrical energy storage device is a device for storing electrical energy, in order to drive the at least one electrical (traction) drive machine. The energy storage device comprises at least one electrochemical energy storage cell. For example, the energy storage device can be a high-voltage accumulator. The energy storage device can expediently be embodied as a battery, in particular as a high-voltage battery. Alternatively or additionally, supercapacitors (referred to for short as supercaps or SCs) can also serve as an energy storage device. Such energy storage devices are generally integrated into an on-board power system.

The energy storage device comprises at least one storage housing. The storage housing has an interior I. The storage housing is expediently a housing which surrounds the components of the energy storage device. The storage housing is expediently embodied in a gas-tight fashion, so that gases which possibly escape from the storage cells are caught. The storage housing is advantageously configured to prevent the ingress of moisture into the energy storage device. The housing can also advantageously serve to protect against fire, contact and/or intrusion. The storage housing is preferably provided in the installation position in such a way that the storage housing is accessible from an underside of the motor vehicle or from the underlying surface in the normal position of the motor vehicle. For example, the storage housing can be accessible from the underbody of the vehicle after the housing cover has been opened.

The storage housing can be manufactured at least partially from a metal, in particular from aluminum, an aluminum alloy, steel or a steel alloy. The storage housing can alternatively be constructed from a plastic, in particular a composite fiber material.

In the at least one storage housing of the energy storage device it is possible to accommodate at least one or more of the following components: storage cells, power electronics components, activated carbon filter, external fuel filter, contactor/contactors for interrupting the power supply to the motor vehicle, cooling elements, electrical conductors, control device/devices, media line/lines for the operating medium container, water container for the injection water, low-voltage battery/batteries, and fuel lines or scavenging air lines. The energy storage device can have, in particular, elements which have to be cooled, in particular storage cells and/or components of the power electronics of the energy storage device. The components are expediently pre-mounted before the module is mounted in the motor vehicle.

The storage housing disclosed here can have, in particular, at least one longitudinal housing support. The longitudinal housing support can be embodied in one piece with a storage housing wall of the storage housing. The longitudinal housing support can be embodied, for example, in a materially joined fashion to the storage housing wall. The longitudinal housing support can expediently be a hollow support.

A honeycomb structure, in particular for absorbing kinetic energy through deformation, can particularly preferably be provided in the longitudinal housing support. The longitudinal housing support can particularly preferably be mounted on the external outside wall of the storage housing. The external outside of the storage housing is the side which in the installation position of the module in the motor vehicle is arranged directly adjacent to an external longitudinal floor support.

The operating fluid container and the at least one storage housing can be arranged in any desired position with respect to one another and can be of any desired shape.

The operating fluid container is preferably at least partially arranged under the rear seats. The operating fluid container is preferably arranged between the heel plate and the rear axle.

In addition, the storage housing can preferably be provided at least partially and preferably completely in the underfloor area of the motor vehicle. The at least one storage housing can be provided at least partially between the central tunnel and the external longitudinal floor support of the bodywork (when viewed in the transverse direction Y of the vehicle). Two storage housings can advantageously be provided, wherein in each case a storage housing is arranged in each individual space between the central tunnel and the external longitudinal floor support. If the motor vehicle does not have a central tunnel, in one advantageous embodiment a storage housing can be provided which extends essentially from a first longitudinal floor support to the second longitudinal floor support. The term “between the central tunnel and the external longitudinal floor support” also comprises, according to the technology disclosed here, refinements which are arranged somewhat above or below the central tunnel or the external longitudinal floor supports in the direction of the vertical axis Z of the vehicle, insofar as the at least one storage housing is arranged between these components when viewed in the transverse direction Y of the vehicle.

In the installation position, the operating fluid container is particularly preferably arranged at least partially and preferably completely above the energy storage device. In other words, in the installation position the tank is therefore further away from the underlying surface than the energy storage device. The storage housing can be arranged underneath the operating fluid container or can project into the operating fluid container in the lower area of the operating fluid container. A particularly favorable center of gravity can therefore be obtained.

The operating fluid container, in particular one container chamber or both of the container chambers, is preferably embodied bearing directly or indirectly on the storage housing. In particular, the operating fluid container and the energy storage device can bear directly one against the other in a bearing area or can be embodied spaced apart from one another by at least one functional element of the module, in particular by the cooling element, disclosed here, of the cooling device. It is therefore advantageously possible to obtain a design which is particularly space-saving and advantageous with respect to the temperature control of the fuel. At least one insulating element and/or fire-prevention element can preferably be provided between the energy storage device (in particular the cells thereof) and the operating fluid container. For example, a double walled structure with integrated insulation can be provided as a common housing wall section. Such elements can advantageously reduce the input of heat into the operating fluid container when the cells experience a thermal event.

The at least one storage housing and the operating fluid container can form a common housing. For example, the operating fluid container can be attached to at least one storage housing, in particular in a materially joined or positively locking fashion and/or using attachment means such as screws, rivets etc. The storage volume of the operating fluid container can be disconnected in an operating-fluidtight fashion from the interior of the (respective) storage housing. The operating fluid container is generally mounted in a non-detachable fashion on the at least one storage housing. At least one opening for servicing work or mounting work can be provided on the common housing. For example, the operating fluid container can be configured in multiple parts, wherein the lower shell can have the common housing section which is disclosed here.

In particular there can be provision that the energy storage device, in particular the common housing wall section disclosed here, is embodied in such a way that operating fluid containers with different contours and/or different storage volumes can be mounted. In other words, it is therefore possible to provide that depending on the vehicle variant the at least one storage housing is embodied as a common part on which different operating fluid containers (in particular adapted to the respective installation situation of the vehicle variant) can be mounted. Such a refinement reduces the variance and constitutes an improved solution with respect to the installation space requirement and weight.

The operating fluid container is particularly preferably a saddle container, wherein each of the container chambers is respectively attached to a storage housing.

In one particularly preferred refinement of the technology disclosed here, the at least one storage housing can be configured to be attached in the installation position to the bodywork of the motor vehicle, and in addition the operating fluid container can be configured to be attached to the bodywork of the vehicle only via the storage housing. Therefore, the at least one storage housing and the operating fluid container are preferably jointly connected to the vehicle bodywork, for example in that the at least one storage housing can be attached to at least one lower longitudinal floor support or side sill and/or to at least one lower transverse floor support. The storage housing can particularly preferably comprise the at least one longitudinal housing support which is disclosed here and on which vehicle bodywork connection points are provided. In another refinement there can be provision that the storage housing can be attached to a vehicle bodywork transverse support underneath the rear seats.

In other words, according to such a refinement the operating fluid container can be embodied in a self-supporting fashion. Expressed once more in a different way, in the installation position the operating fluid container may not be capable of being connected or be connected in a directly positively locking or materially joined fashion to vehicle bodywork connection points on the vehicle bodywork. Therefore, the operating fluid container expediently does not have any load-bearing vehicle bodywork connection points which are necessary to absorb the forces and torques which result from the intrinsic weight of the operating fluid container and operating fluid. Instead, the operating fluid container can bear these loads itself. Such a refinement permits particularly space-saving integration of the storage housing and operating fluid container in the motor vehicle.

In one particularly preferred refinement, the operating fluid container is configured to transmit forces and/or torques from a first storage housing to a second storage housing. For this purpose, the operating fluid container can have at least one reinforcement element which preferably starts at the first storage housing and ends at the second storage housing. The overall rigidity of the vehicle bodywork can therefore be advantageously improved.

The operating fluid container and the energy storage device can have at least one common housing wall section. The common housing wall section can separate in a fluidtight fashion the operating fluid which can be stored in the operating fluid container from the interior I of the energy storage device. The common housing wall section can form the single fluidtight separating wall between the interior I and the operating fluid container.

According to the technology disclosed here, the energy storage device or the operating fluid container can be embodied in such a way that before the assembly of the module the housing wall section is provided only on the energy storage device or on the operating fluid container. In particular, before the assembly of the module the common housing wall section

i) can be formed by an outer wall of the operating fluid container, in particular on the lower shell on which at least one storage housing can be mounted with a recess corresponding to the common housing wall section; or
ii) is formed by an outer wall of the at least one storage housing on which the operating fluid container (100) is to be mounted with a corresponding recess;

In other words, the technology disclosed here provides, in one refinement, that instead of two housing wall sections of the operating fluid container and the storage housing which are to bear one against the other, a separating wall is provided which separates the operating fluid from the interior I.

The module disclosed here can have at least one cooling device with at least one cooling element for the common cooling of the operating fluid container and of the energy storage device. For this purpose, the operating fluid container and the energy storage device expediently bear directly one against the other in the bearing area or are spaced apart from one another by the at least one cooling element of the cooling device. In particular, the at least one cooling element can be provided in the bearing area or directly adjacent to the bearing area. The cooling element can particularly preferably be provided on the common housing wall section disclosed here. The term “adjacent to the bearing area or housing wall section” means in this context that the at least one cooling element is connected in a heat-conducting fashion to the bearing area or housing wall section without impairing the cooling effect (e.g. losses on the transportation distance are less than 20% or less than 10%).

The cooling element is particularly preferably provided as a cooling duct through which cooling medium flows in or on a housing wall of the storage housing. Such a cooling duct structure can be integrated and manufactured in a comparatively easy geometric fashion. Such a cooling duct structure can moreover be satisfactorily adapted to the external contour of the operating fluid container. Therefore, only one cooling device for the operating fluid container and energy storage device is particularly preferably provided.

The cooling duct can particularly preferably extend over the entire length of the storage housing.

The at least one cooling element can have two opposite sides, wherein a first side of the two sides is configured to cool the operating fluid, and wherein a second side of the two sides is configured to cool elements of the energy storage device which are to be cooled.

The module can have at least one cooling fin and preferably a multiplicity of cooling fins, in particular preferably in the common housing section, which cooling fin/cooling fins is/are connected in a heat-conducting fashion to at least one cooling element. The at least one cooling fin can project into the interior I of the energy storage device and/or into the storage volume S of the operating fluid container. Alternatively or additionally, the at least one cooling element can itself project into the interior I of the energy storage device and/or into the storage volume S of the operating fluid container. The operating fluid container expediently does not comprise any separate cooling devices, but instead is temperature-controlled only by the common cooling device. In the installation position, the at least one cooling element is expediently provided above the elements of the energy storage device which are to be cooled. It is therefore possible to achieve better cooling. In particular, the elements which are to be cooled can be arranged in the bearing area or in the common housing section.

The disclosed technology relates, in particular, to a storage cell for storing electrical energy, in particular for the energy storage device disclosed here. The storage cell comprises electrical connections and can generally comprise at least one cell vent. In the installation position of the storage cell in the motor vehicle, the electrical connections can be arranged lower

i) than the cell vent (if one is provided); and/or
ii) than the attachment section for the direct or indirect attachment of the storage cell, in particular to the storage housing of the energy storage device.

The technology disclosed here comprises, in particular, a module with at least one such storage cell, preferably the module disclosed here, wherein an operating fluid container does not have to be provided. A multiplicity of storage cells are generally provided in the at least one storage housing of the energy storage device. The storage cells are therefore expediently attached suspended from the storage housing. The storage cells are preferably combined to form a plurality of modules, and the respective modules or groups can be dismounted individually. A group or a module is here a number of storage cells which have already been connected to one another (e.g. clamped to one another) before mounting, wherein the number of storage cells is smaller than the overall number of storage cells. The module particularly preferably comprises a storage housing with storage cells which can be dismounted in the installation position from the storage housing individually or in a plurality of groups, without the totality of the storage cells or groups having to be dismounted (i.e. removed from the installation position thereof) for this purpose. For example, the individual storage cells can be successively attached or released upside down from the installed storage housing. For example, the storage cells can be attached or mounted by means of a screwed connection and/or latched connection. Advantageously, an attachment rail can be provided on the upper part of the storage housing to which rail the multiplicity of storage cells can be releasably attached.

A housing cover can also advantageously be provided in the storage housing floor. In other words, the storage housing is also mounted upside down in the installation position so that the interior I of the storage housing is accessible from the vehicle underbody after the housing cover is opened.

Therefore, the individual storage cells are advantageously more easily accessible for any service work or maintenance work. If a storage cell is defective or degraded, this storage cell can be individually exchanged without the other storage cells having to be dismounted at the same time. In addition, the electrical connections of the storage cells are more easily accessible for any checking measurements.

A cooling element of the energy storage device is particularly preferably provided above the storage cell. The cooling element is particularly preferably connected in a heat-conducting fashion to at least one end side of the storage cell, expediently the end side which is arranged at the top in the installation position.

The storage housing of the storage device can have at least one media line which is fluidically connected or can be fluidically connected to the operating fluid container and is at least partially accommodated in the storage housing.

A media line can be an operating fluid line which is provided for transporting operating fluid. For example, the media line can be a fuel line, water line or a combustible line. In addition, a media line of the operating fluid container is a scavenging air line which feeds, for example, scavenging air to the activated carbon filter. However, the exhaust system of an internal combustion engine is not to be considered a media line of the operating fluid container.

The media line can be particularly preferably at least partially accommodated in the at least one longitudinal housing support disclosed here. The media line can particularly preferably project with at least 50% or at least 70% of its media line transverse section into the internal volume V of the longitudinal housing support. In one particularly preferred refinement, the at least one media line is completely accommodated in a longitudinal support which is embodied as a hollow section.

The longitudinal housing support can also expediently be embodied in such a way that the at least one media line can be pushed into the longitudinal housing support. This facilitates the mounting or dismounting of the at least one media line.

Alternatively or additionally, the at least one media line can be at least partially accommodated in a storage housing wall. The storage housing wall which at least partially accommodates the media line can be provided, for example,

i) in the housing cover,
ii) on the internal outside wall, and/or
iii) on the external outside wall.

The at least one media line can be attached to the storage housing using suitable attachment means.

In one preferred refinement, the storage housing wall and/or the longitudinal housing support has at least one section with a C-shaped or U-shaped cross section in which the at least one media line is or can be accommodated. Therefore, the at least one media line can be advantageously attached using simple means. It is therefore possible to provide an open contour, wherein the contour opening serves to mount the media line. Such a section can be manufactured, for example, with a C-shaped or U-shaped cross section by stamping, roll forming, extrusion molding etc.

The media line can advantageously be capable of being attached to the storage housing by means of a clip connection.

The storage housing can expediently have an elastomer bearing, wherein the media line can be accommodated in the elastomer bearing. The elastomer bearing can advantageously be arranged in the C-shaped or U-shaped cross section or in the clip. Such an elastomer bearing generally simplifies mounting. The elastomer bearing becomes clamped in the installation position and as a result builds up the holding forces. The elastomer bearing can equally deform elastically during mounting.

The internal outside wall of the storage housing is arranged closer to the vehicle longitudinal axis running through the center of the vehicle than the external outside wall. In other words, the external outside wall is arranged closer to the side sills than the internal outside wall. Depending on the vehicle configuration it may be advantageous to arrange the media line on the internal outside wall or on the external outside wall of the storage housing. For example, in the case of a media line on an internal outside wall the probability of mechanical deformation can be lower, whereas the thermal effects of an exhaust system on the fuel to be fed could be greater here. On the other hand, in the case of a media line on an external outside wall the probability of mechanical deformation can be greater, whereas here the thermal effects of the exhaust system on the fuel to be fed are generally smaller.

The longitudinal housing support can advantageously be mounted on the external outside wall of the storage housing. The external outside wall is arranged spaced apart from the central tunnel or from the exhaust system. Therefore, an input of heat which is caused by the exhaust system into the fuel flowing through the media line can be advantageously reduced or avoided.

In one refinement, the longitudinal housing support is an extruded profile. However, other types of manufacture are also conceivable.

The system disclosed here also comprises at least one control device. The control device is configured, inter alia, to implement the technology disclosed here and, in particular, the method steps disclosed here. For this purpose, the control device can perform at least partial and preferably complete closed-loop control or open-loop control of the actuators of the system on the basis of signals which are provided. Alternatively or additionally, the control device can also be integrated into another control device, for example into a superordinate control device. The control device can interact with other control devices of the motor vehicle.

The control device can be premounted, or completely integrated, into the store or the common housing.

According to the technology disclosed here a synergetic installation space is provided, in particular there is provision that all the components and subcomponents of the high-voltage accumulator, the operating fluid and the control devices and subcomponents (S box, ACF&CN filter) and various resources (cables, lines, etc.) are positioned at a central location in the vehicle (inter alia in the underfloor and rear seat), in particular in a housing.

In this context, the integration concept can be embodied as a housing in such a way that the different energy carriers (fuel, storage cells) are arranged adjacent to one another in a common housing. Through the synergetic use of the supporting function of the housing for the operating fluid container and encapsulation of the high-voltage accumulator it is possible to generate more storage content for the energy carriers in the same installation space. Additional dividing walls (a housing wall of the high-voltage accumulator and a housing wall of the operating fluid container) as well as mounting distances between the operating fluid container and the high-voltage accumulator can therefore be dispensed with and replaced by a single separating wall without a mounting distance. This design additionally permits incorporation of operating fluid container and high-voltage accumulator components and subcomponents. The pre-mounting work in a housing preferably additionally permits further components such as activated carbon filter (ACF) and external fuel filter (CN filter) and lines to be integrated into the housing. The structural integrity and use of the synergetic structure function for high-voltage accumulators and operating fluid containers permit increased robustness and crash safety of the vehicle bodywork with respect to two or more separate components.

The synergetic use of the central installation space in the underfloor/rear area in just one housing constitutes, in conjunction with the resulting advantages of common (pre-) mounting, the core of the disclosure as functional aspects. The high degree of integration in the central housing minimizes the risk of unprotected electrical connections, critical connections in the saddle installation space are therefore significantly simplified. Optimized routing of lines, by stamping in the cover part, is made possible by the central housing and brings about advantages in terms of packaging and mounting. Mounting/mounting is facilitated by the reduction to one component. A pressure tank (fuel) is made possible with a different selection of material and design, and joint mounting therefore becomes possible.

In this context, the integration concept provides a housing which is embodied in such a way that different energy carriers (aggregate states) find a synergetic installation space. The housing which is expediently located in the underfloor of the vehicle and has a hybrid or multi-material design can accommodate all components and subcomponents in such a way that they can be filled with respective media. Resources (cables, lines, etc.) can be positioned or embodied next to them. The structural integrity and functional integration can increase the robustness and crash safety of the vehicle bodywork shell here. The lines, in particular the media lines, can be laid or integrated in the longitudinal profiles. The lines can be accommodated in the module before it is mounted in the motor vehicle. The lines can be integrated into the lateral crash structure supports. The crash structure supports can be embodied in such a way that they can be deformed for reasons of weight and because of the absorption of energy, for example as hollow chamber sections. The at least one line can be pre-mountable by means of a line insertion system. The at least one line can be a line package comprising at least one fuel line and at least one scavenging air line.

The means of securing the line in the housing can be implemented by stamping and/or by means of an extruded section. It is possible, for example, to provide a piece of sheet metal with a contour which is open on one side. The line can be inserted from the outside with an elastomer bearing, which can simplify the mounting. The elastomer bearing which is located on the line can be mounted into the C-shaped contour during mounting, as a result of which a positively locking assembly can be produced. Pressing of the elastomer in conjunction with a section which tapers toward the outside. Lines or components can preferably be provided in a stamped cover or floor of the high-voltage accumulator. Routing of the line by stamping in the cover part permits the package to be used better for lines in the vehicle by means of additional securing elements. A pressure tank (fuel) is advantageously made possible here with a different selection of materials and designs. The elimination of attachment means for the respective lines and the possibility of routing them at a distance from an exhaust system (input of heat into adjacent components) can be further advantages.

The preferred integration of the cooling system by means of the extended housing for the synergetic use of the common installation space (preferably underfloor/rear seat) for high-voltage accumulators (HVS) including storage management electronics (SME) and fuel tank/fuel supply systems (KVA) and similar containers constitutes an aspect of the technology disclosed here. The integration of all the components and subcomponents in the storage housing can permit lengthening/extension of the cooling elements used to cool the high-voltage accumulator into the installation space of the operating fluid container, as a result of which the operating fluid can also be cooled. The efficiency can be advantageously improved by means of the cooling mechanism. The cooling element can be routed through the separating wall and sealed or welded hermetically.

The technology disclosed here advantageously entails one or more of the following advantages:

improvement in respect of utilization of the installation space, weight and costs through component reduction, in particular reducing the number of components and their mounting distances and separating walls;

simplified mounting of components which are otherwise difficult to access by virtue of component reduction and pre-mounting;

reduction or elimination of mounting devices such as securing straps, clamps and other attachment resources through component reduction;

improved rigidity through an at least partially load-carrying operating fluid container;

the structural integrity can be increased;

improved crash values and strength values of the motor vehicle;

improved crash safety of the vehicle bodywork;

reduced probability of unprotected electrical connections by virtue of a common housing;

better line routing through at least partial integration of the line routing into the housing, reduces line damage, probability of unprotected connections, weight, installation space requirement and manufacturing costs; and/or reduction of the gas emissions through discharging of heat out of the operating fluid container or reduced inputting of heat into the operating fluid.

The technology disclosed here will now be explained on the basis of the figures, in which:

### BRIEF DESCRIPTION OF THE DRAWINGS

FIG. 1 shows a schematic cross-sectional view of the module along the sectional line I-I in FIG. 2;

FIG. 2 shows a schematic cross-sectional view of the module along the sectional line II-II in FIG. 1;

FIG. 3 shows a schematic plan view of the module along the line in FIG. 2;

FIGS. 4-7 shows various schematic views of a motor vehicle with the module disclosed here;

FIG. 8 shows a schematic cross-sectional view of a further module;

FIG. 9 shows a schematic cross-sectional view of a further module; and

FIG. 10 shows a schematic cross-sectional view of a storage cell.

### DETAILED DESCRIPTION OF THE DRAWINGS

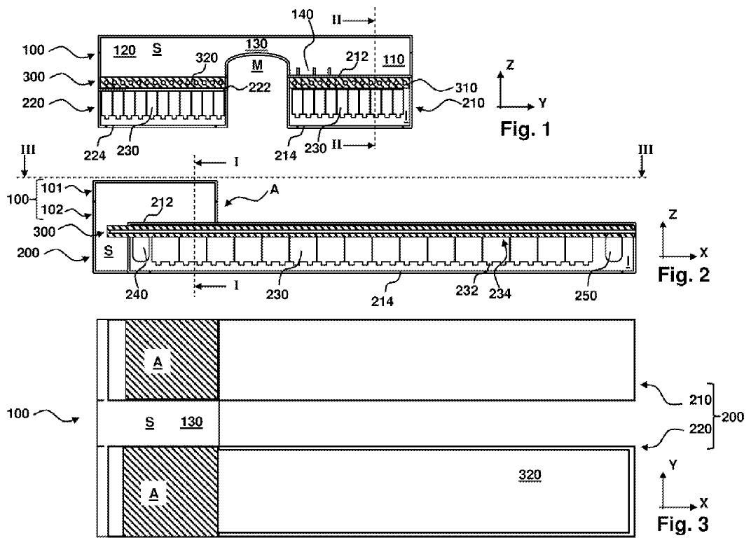

FIGS. 1 to 3 show various schematic cross-sectional views of the module disclosed here. The module comprises an operating fluid container 100, which is embodied here as a saddle container. The operating fluid container 100 comprises two container chambers 110, 120 as well as a connecting area 130. The connecting area 130 connects the two container chambers 110, 120 over the central tunnel M here. The operating fluid container 100 has a storage volume S. The operating fluid container 100 is embodied here by a lower shell 102 and an upper shell 101. There could likewise be provision that three or more parts form the operating fluid container 100.

The module also comprises an energy storage device 200 with two storage housings 210, 220. A plurality of components of the energy storage device 200 are accommodated in the storage housings 210, 220 here. In particular, the storage housings can accommodate one or more of the following elements: storage cells 230, components of the power electronics 240, activated carbon filters, external fuel filter, contactor/contactors for interrupting the power supply to the motor vehicle, cooling element/elements, electrical conductors, control device/devices, media line/lines for the operating fluid container 100, water container, low-voltage battery/batteries, etc.

The module is shown here in the installation position, indicating how in the installed state the module is arranged in a horizontally oriented motor vehicle.

Each of the container chambers 110, 120 is respectively mounted here on one of the two storage housings 210, 120 in the bearing area A. Here, the operating fluid container 100 does not have any further vehicle bodywork connecting points via which the operating fluid container is attached to the bodywork of the motor vehicle. The vehicle bodywork connecting points of the storage housings 210, 220 have been omitted for the sake of simplification. The operating fluid container 100 is mainly arranged above the storage housings 210, 220 (cf. FIG. 1). The lower shell 102 of the operating fluid container 100 at least partially surrounds the storage housings 210, 220 here (cf. FIG. 2).

The operating fluid container 100, in particular the container chambers 110, 120, can each form a common housing wall section 212, 222 with the respective storage housing 210, 220. The common housing wall section 212, 222 is the single fluidtight separating wall between the storage volume S of the operating fluid container 100 and the interior I of the energy storage device 200. Consequently, according to the technology disclosed here two separate, fluidtight housing wall sections of the operating fluid container 100 and energy storage device 200 are not laid on top of one another or attached to one another but rather instead merely a single separating wall is provided. Such single-walled configuration reduces the required space and the overall weight of the module in comparison with a double-walled solution. In order to form the fluidtight separating wall in a semifinished product of the storage housing or in a semifinished product of the operating fluid container it is expedient to provide the separating wall, wherein this separating wall is connected to a corresponding recess in the respective other semifinished product during the combination of the operating fluid container 100 and energy storage device 200. However, such a single fluidtight separating wall does not have to be provided.

The module comprises a cooling device 300. The cooling device 300 comprises two cooling elements 310, 320. The two cooling elements 310, 320 are provided in the bearing area A here. The first cooling element 310 is provided here within the storage housing 210. The first cooling element 310 is connected here in a heat-conducting fashion to cooling fins 140 which project into the storage volume S. The second cooling element 320 is, however, arranged outside the storage housing 220 (cf. FIG. 1 & FIG. 3). The cooling elements 310, 320 are arranged here in such a way that they can cool both the operating fluid in the operating fluid container 100 and the energy storage device 200. The two cooling elements 310, 320 each have a first side which is configured to cool the operating fluid, and a second side which is configured to cool elements 230, 240, 250 of the energy storage device 200 which are to be cooled.

In one refinement of the technology disclosed here, the cooling element (here the second cooling element 320) can project into the storage volume S of the operating fluid container 100. Of such a refinement, part of the second side can therefore also cool the operating fluid. The cooling elements 310, 320 particularly preferably extend over the entire length of the first and second storage housings 210, 220. The cooling elements 310, 320 are expediently formed by cooling ducts. While the motor vehicle is operating, these cooling ducts have, for example, a flow of coolant, which also cools other components of the motor vehicle such as, for example, the internal combustion engine and/or the electric drive machine. The shape of the housing of the operating fluid container 100 or of the storage housing 210, 220 often depends on the specific installation position in the motor vehicle and is significantly influenced by it. Cooling ducts can be satisfactorily adapted to the housing geometries which differ owing to the installation situation. Instead of the plate-shaped geometry of the cooling elements 310, 320 illustrated here, it is also equally possible to provide other geometries and cooling elements which are embodied and arranged in a different way.

In the storage housings 210, 220, a multiplicity of storage cells 230 are attached suspended from the respective storage housing upper side. The attachment section 232 is arranged above the electrical connections 234 here (cf. FIG. 2 and FIG. 10). In other words, in the installation position the attachment section 232 is further away from the underlying surface than the electrical connections 234. Likewise, the cell vent 236 (cf. FIG. 10) of a storage cell 230 can also be respectively arranged above the electrical connection 234. A housing cover 214, 224 can be advantageously provided in the storage housing floor, that is to say in the side facing the underlying surface in the installation position. Said housing cover 214, 224 can be expediently mounted in a detachable fashion on the storage housing 210, 220. This cover can therefore be advantageously opened during maintenance deployment or servicing deployment. The individual storage cells 230 can then be advantageously individually checked and exchanged without dismounting further securing elements. Further components of the energy storage device 200, such as for example the components of the power electronics 240 or the control device 250, can equally be mounted in a suspended fashion or upside down in the installation position of the storage housing 210, 220. The at least one cooling element 310, 320 is particularly preferably provided above the at least one storage cell 230, in particular in such a way that the cooling element 310, 320 cools the upper end face of the storage cell 230. For this purpose, the cooling element 310, 320 can be connected to the end face in a heat-conducting fashion. The attachment section 232 can be particularly preferably provided on or directly adjacent to the end face. More uniform cooling of the storage cells 230 can be therefore advantageously achieved, which can have a positive effect on the degradation of the storage cells. The suspended storage cells 230 and their connection to the cooling elements 310, 320 are merely a preferred refinement. In one preferred refinement, the storage cells 230 could also be provided standing on the storage housing floor.

The shape and the size of the operating fluid container 100 can vary depending on the installation situation in the vehicle variant. Likewise, just one storage housing can be provided.

In order to visualize different embodiment variants, the attachment of the container chambers 110, 120 to the respective storage housings 210, 220 and the arrangement of the cooling elements 310, 320 is configured differently here. Preferably in each case two attachments are configured the same and two cooling elements 310, 120 which are configured the same are used in a motor vehicle.

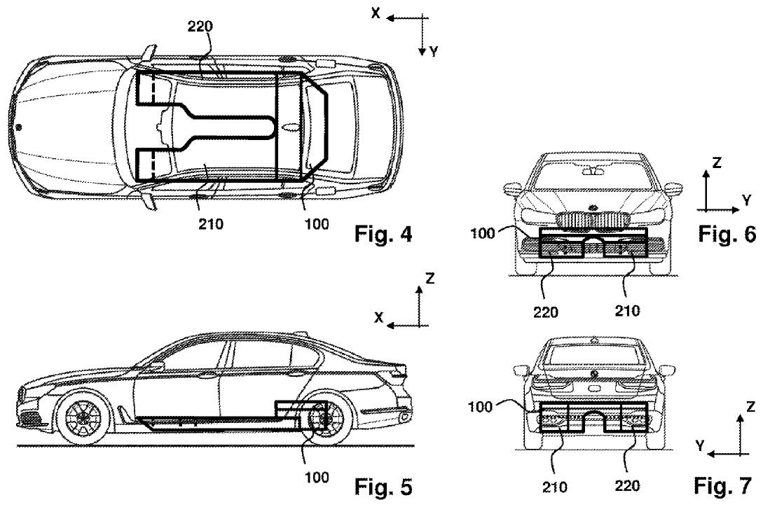

FIGS. 4-7 show different schematic views of a motor vehicle with the module disclosed here. The storage housings 210, 220 start here under the rear seats and extend far into the underfloor area. The storage housings 210, 220 end here at the level of the dashboard in the longitudinal direction of the vehicle.

The operating fluid container 100 at least partially encloses the storage housings 210, 220. In the upward direction, the operating fluid container 100 is bounded by the rear seats here. In the direction of the vehicle longitudinal axis X, the heel plate and the rear axle bound the operating fluid container 100. The operating fluid container 100 can be embodied in multiple parts here.

A central tunnel M is provided in the motor vehicle illustrated here. The operating fluid container 100 is therefore embodied as a saddle container. In addition, two separate storage housings 210, 220 are provided. However, this does not have to be the case. In a front wheel drive motor vehicle the central tunnel M could be made smaller or be dispensed with. Then, for example a single storage housing which passes through in the transverse direction Y of the vehicle and a single container chamber which passes through in the transverse direction Y of the vehicle could be provided.

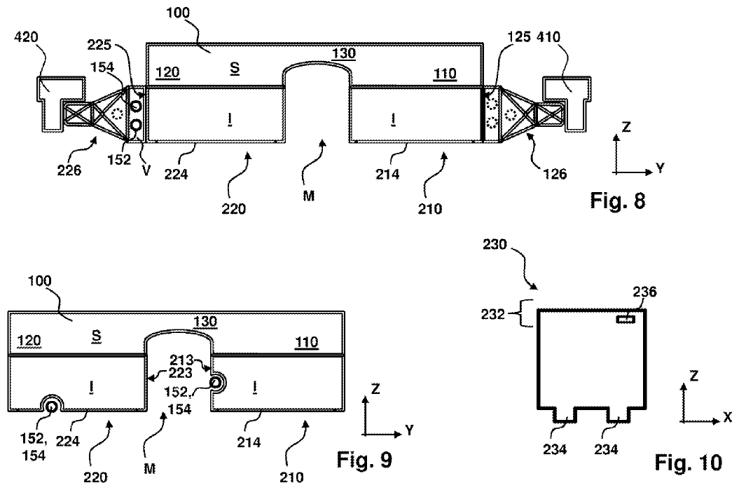

FIG. 8 shows a further refinement of the module disclosed here. The specific requirement and arrangement of the electronic components of the energy storage device 200 have been omitted for the sake of simplicity. In FIG. 8, the focus is on the longitudinal housing supports 216, 226 and the media lines 152, 154. All the other components of the module can be configured as disclosed in conjunction with the other figures or in the general part. The storage housings 110, 220 each have a longitudinal housing support 216, 226 here.

The longitudinal housing supports 216, 226 can be attached, for example, to the external outside walls 215, 225 in a materially joined fashion. The longitudinal housing supports 216, 226 are embodied here as hollow supports and have a honeycomb structure. Such a longitudinal housing support 216, 226 is advantageously configured to reduce kinetic energy occurring in the case of a collision by means of plastic deformation. The honeycomb structure can advantageously have a plurality of chambers. At least one media line 152, 154 can particularly preferably be accommodated in the longitudinal housing support 216, 226. The media line 152, 154 is expediently accommodated in the chamber which directly adjoins the storage housing 210, 220. The media lines 152, 154 are completely accommodated here. Alternatively there may be provision that the media line cross section is accommodated only partially, as is described in more detail below in conjunction with FIG. 9. The storage housings 210, 220 are arranged here in the underfloor area between the external longitudinal floor supports 410, 420. The external longitudinal floor supports can have any suitable cross-sectional profile. Attachment means with which the longitudinal housing supports 216, 226 are connected here to the external longitudinal floor supports 410, 420 are not illustrated here. Further media line, which can also be routed through the longitudinal housing supports 216, 226, are indicated by dots. The vehicle bodywork connection of the energy storage device 200 to the vehicle bodywork, in particular the longitudinal housing support 216, 226 disclosed here, can also be configured differently. Likewise, the media routing means from or to the operating fluid container can also be embodied in a different way.

FIG. 9 shows a further refinement of the technology disclosed here. Only the differences in comparison with the preceding refinements are explained below. In FIG. 9, the components of the energy storage device 200 and the vehicle bodywork connection have been omitted for the sake of simplicity. The storage housings 210, 220 comprise here a storage housing wall with a section which has a C-shaped or U-shaped cross section. This section can be provided, for example, on an internal outside wall 213, 223 or on a housing cover 214, 224. In the installation position, for example the at least one media line 152, 154 can be routed in this section. The media line 152, 154 can be accommodated completely or only partially. At least 50% or at least 70% of the media line cross section is preferably accommodated in the C-shaped or U-shaped section. The arrangement of the media line 152, 154 as shown here is more space-saving, safer with respect to intrusion and/or can be more easily mounted and dismounted. Possible elastomer bearings, which can secure the media line 152, 154, are not shown here.

FIG. 10 shows an enlarged view of a storage cell 230 in the installation position. The cell vent 236 and the attachment sections 232 are arranged above the electrical connection 234 here. The storage cell 230 can otherwise have any suitable shape.

The term “above” means in conjunction with the technology disclosed here that in the installation position the component (e.g. “cooling element 310”, cf. FIG. 1) which is arranged above is spaced further apart from the underlying surface in the direction of the vertical axis Z of the vehicle than a component (e.g. “storage cell 230”. cf. FIG. 1) which is arranged below in comparison thereto. In the figures illustrated here, the Z axis denotes the vertical axis of the vehicle, the X axis denotes the longitudinal direction of the vehicle and the Y axis denotes the transverse direction of the vehicle.

Preferred refinements are illustrated in the figures. It is equally conceivable that the operating fluid container 100 and the energy storage device 200 are embodied in different ways, for example in respect of their size, their geometric shape and/or number of housings.

For ease of reading and for the sake of simplification the expression “at least one” has been omitted in some cases. Insofar as a feature of the technology disclosed here is described in the singular or in an indefinite fashion (e.g. the/an upper shell, the/a lower shell, the/a container chamber, the/a connecting area, the/a cooling fin, the/a media line, the/a energy storage device, the/a storage housing, the/a common housing wall section, the/a outside wall, the/a housing cover, the/a longitudinal housing support, the/a storage cell, the/a component, the/a control device, the/a cooling device, the/a cooling element, the/a longitudinal floor support etc.), the plurality thereof is intended also to be disclosed at the same time (e.g. the at least one upper shell, the at least one lower shell, the at least one container chamber, the at least one connecting area, the at least one cooling fin, the at least one media line, the at least one energy storage device, the at least one storage housing, the at least one common housing wall section, the at least one outside wall, the at least one housing cover, the at least one longitudinal housing support, the at least one storage cell, the at least one component, the at least one control device, the at least one cooling device, the at least one cooling element, the at least one longitudinal floor support etc.).

The term “essentially” (e.g. “essentially vertical axis”) comprises, in the context of the technology disclosed here, in each case the precise property or the precise value (e.g. “vertical axis”) as well as in each case differences which are insignificant for the function of the property/of the value (e.g. “tolerable difference from the vertical axis”).

The above description of the present disclosure serves only for illustrative purposes and not for the purpose of limiting the disclosure. Various changes and modifications are possible within the scope of the disclosure without departing from the scope of the disclosure or its equivalents.

### LIST OF REFERENCE SYMBOLS

100 Operating fluid container
101 Upper shell
102 Lower shell
110, 120 Container chambers
130 Connecting area
140 Cooling fins
152, 154 Media lines
200 Energy storage device
210, 220 Storage housing
212, 222 Common housing wall section
213, 223 Internal outside wall
214, 224 Housing cover
215, 225 External outside wall
216, 226 Longitudinal housing support
230 Storage cell
240 Components of the power electronics
250 Control device
300 Cooling device
310, 320 Cooling element
410, 420 Longitudinal floor support
I Interior I
M Central tunnel
S Storage volume
V Internal volume

1.-26. (canceled)

27. A module for a motor vehicle, comprising:
at least one operating fluid container configured to store an operating fluid which is liquid under ambient conditions;
at least one energy storage device configured to store electrical energy; and
a cooling device with at least one cooling element configured to commonly cool the operating medium container and the energy storage device.

28. The module according to claim 27, wherein the operating fluid container and the energy storage device configured to bear directly or indirectly one against the other in a bearing area (A).

29. The module according to claim 28, wherein the at least one cooling element is provided in the bearing area (A) or directly next to the bearing area (A).

30. The module according to claim 29, wherein
the operating fluid container and the energy storage device have at least one common and single-walled housing wall section, and
the at least one cooling element is provided in or directly next to the common housing wall section.

31. The module according to claim 30, wherein the cooling element is configured as a cooling duct which is provided in or on a housing wall of the storage housing.

32. The module according to claim 31, wherein
the at least one cooling element has two sides,
a first side of the two sides is configured to cool the operating fluid, and
a second side of the two sides is configured to cool elements of the energy storage device which are to be cooled.

33. The module according to claim 32, wherein
the at least one cooling element projects into the interior of the energy storage device and/or into the storage volume (S) of the operating fluid container; and/or
the module has at least one cooling fin which is connected in a heat-conducting fashion to at least one cooling element; and
the at least one cooling fin projects into an interior of the energy storage device and/or into a storage volume (S) of the operating fluid container.

34. The module according to claim 33, wherein the at least one cooling element is provided above elements of the energy storage device which are to be cooled.

35. The module according to claim 34, wherein the elements of the energy storage device which are to be cooled are arranged at least in one of the bearing area (A), and in the common housing wall section, on the storage housing of the energy storage device.

36. The module according to claim 35,
wherein at least one media line which is or can be fluidically connected to the operating fluid container is accommodated at least partially in the storage housing.

37. The module according to claim 36, wherein the storage housing has a longitudinal housing support.

38. The module according to claim 37, wherein
the longitudinal housing support is configured in one piece with a storage housing wall of the storage housing;
the longitudinal housing support is configured as a hollow carrier;
the longitudinal housing support is an extruded profile; and/or
a honeycomb structure is provided in the longitudinal housing support.

39. The module according to claim 38, wherein the media line is accommodated at least partially in the longitudinal housing support.

40. The module according to claim 39, wherein the longitudinal housing support is configured in such a way that the at least one media line can be pushed into the longitudinal housing support.

41. The module according to claim 40, wherein
the longitudinal housing support is mounted on an external outside wall of the storage housing, and
in the installation position of the module the external outside wall is arranged directly adjacent to an external longitudinal floor support.

42. The module according to claim 41, wherein the at least one media line is at least partially accommodated in a storage housing wall.

43. The module according to claim 42, wherein the storage housing wall and/or the longitudinal housing support has at least one section with a C-shaped cross section or U-shaped cross section in which the media line is accommodated.

44. The module according to claim 43, wherein the media line can be attached to the storage housing via a clip connection.

45. The module according to claim 44, wherein
the storage housing has an elastomer bearing, and
the media line is accommodated in the elastomer bearing.

46. The module according to claim 45, wherein the media line is a fuel extraction line or a scavenging air line.

47. The module according to claim 46, wherein in the installation position the elements of the energy storage device which are to be cooled are mounted suspended from the or a storage housing of the energy storage device.

48. The module according to claim 47, wherein
the component which is to be cooled is a storage cell, and
in the installation position of the storage cell the electrical connections are arranged lower than a cell vent of the storage cell.

49. The module according to claim 48, wherein
the component which is to be cooled is a storage cell, and
in the installation position of the storage cell the electrical connections are arranged lower than an attachment section for attaching the storage cell.

50. The module according to claim 49, wherein in order to cool at least the energy storage device, at least one cooling element is provided at least in certain areas above the storage cells.

51. The module according to claim 50, further comprising: a housing cover that is provided in a storage housing floor of the storage housing.

52. A motor vehicle comprising at least one module according to claim 51.
